(19) United States
(12) Patent Application Publication
(10) Pub. No.: US 2009/0041990 A1
(43) Pub. Date: Feb. 12, 2009

(54) METHOD FOR ATTACHMENT OF SOLDER POWDER TO ELECTRONIC CIRCUIT BOARD AND SOLDERED ELECTRONIC CIRCUIT BOARD

(75) Inventors: Takashi Shoji, Tokyo (JP); Takekazu Sakai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 12/066,369

(22) PCT Filed: Sep. 6, 2006
(86) PCT No.: PCT/JP2006/318099

§ 371 Date: Sep. 19, 2008

Related U.S. Application Data
(60) Provisional application No. 60/718,737, filed on Sep. 21, 2005.

(30) Foreign Application Priority Data
Sep. 9, 2005 (JP) 2005-261835

(51) Int. Cl. H05K 3/34; H05K 3/24; B23K 3/06

(52) U.S. Cl. 428/195.1; 427/97.3; 427/560; 427/97.4

(57) ABSTRACT

A method for the attachment of solder powder includes the steps of treating an exposed metallic surface of an electronic circuit board with a tackifier compound, thereby imparting tackiness to the metallic surface to form a tacky part, and supplying the tacky part with a solder powder slurry suspended in a liquid, thereby inducing attachment of the solder powder. A method for the production of a soldered electronic circuit board, includes the steps of treating an exposed metallic surface of an electronic circuit board with a tackifier compound, thereby imparting tackiness to the metallic surface to form a tacky part; supplying the tacky part with a solder powder slurry suspended in a liquid, thereby inducing attachment of the solder powder, and thermally fusing the attached solder powder, thereby forming a circuit. A method for the attachment of solder powder includes the steps of treating an exposed metallic surface of an electronic circuit board with a tackifier compound, thereby imparting tackiness to the metallic surface to form a tacky part, supplying the tacky part with a solder powder slurry suspended in a liquid, thereby inducing attachment of the solder powder and, on the occurrence of a part devoid of attachment of solder powder in the consequently formed electronic circuit board, supplying the part with a solder powder slurry, thereby inducing attachment of solder powder thereto.

### CROSS REFERENCE TO RELATED APPLICATIONS

This application is an application filed under 35 U.S.C. §111(a) claiming the benefit pursuant to 35 U.S.C. §119(e)(1) of the filing dates of Provisional Application No. 60/718,737 filed Sep. 21, 2005 and Japanese Patent Application No. 2005-261835 filed Sep. 9, 2005 pursuant to 35 U.S.C. §111(b).

### TECHNICAL FIELD

This invention relates to a method for definitely attaching solder powder exclusively to an exposed fine metallic surface of an electronic circuit board (inclusive of a printed-wiring board), a method for fusing the solder powder and forming a solder layer on the exposed metallic surface with the object of mounting an electronic part on the electronic circuit board, and an electronic circuit board having a solder precoat formed thereon.

### BACKGROUND ART

In recent years, electronic circuit boards, such as electronic circuit boards having electronic circuit patterns formed on insulating substrates, such as plastic substrates (possibly inclusive of films), ceramic substrates or metallic substrates coated with a plastic material, have been developed and means of configuring electronic circuits by soldering electronic parts, such as IC devices, semiconductor chips, resistors and capacitors, on distribution planes have been extensively adopted.

In this case, the purpose of bonding the lead terminals of electronic parts to the prescribed parts of a given circuit pattern is ordinarily achieved by having a solder precoat formed in advance on an electrically conductive circuit electrode (metal) surface exposed on an electronic circuit board, printing solder paste or flux thereon, setting the prescribed electronic parts in position, and subsequently causing the solder precoat to reflow either alone or in conjunction with the solder paste, thereby soldering the relevant components.

Recently, the trend of the electronic products toward miniaturization has been urging the electronic circuits to use fine pitches. Parts of fine pitches such as, for example, QFP (Quad Flat Package)-type LSI and CSP (Chip Size Package) using a 0.3 mm pitch, FC (Flip Chip) using a 0.15 mm pitch, MCM (Multi Chip Module), SiP (System in Package, PoP (Package on Package) and 3DP (3 Dimensional Package) are being copiously mounted within small areas. Thus, the electronic circuit boards are required to possess definite solder circuit patterns that conform to such fine pitches.

For the purpose of forming the solder precoat on the electronic circuit board, the plating method, the HAL (Hot Air Leveler) method, or the method that comprises the steps of printing a paste of solder powder and reflowing the produced print is followed. The method for producing a solder circuit by the plating technique, however, encounters difficulty in giving the solder layer a necessary thickness. The HAL method and the method relying on printing the solder paste incur difficulty in conforming to a fine pitch pattern.

Thus, as a means to form a solder precoat on the electronic circuit board without requiring such a troublesome operation as the alignment of a circuit pattern, a method that comprises causing a tackifier compound to react with the electrically conductive circuit electrode surface of an electronic circuit board, thereby imparting tackiness to the surface, attaching solder powder to the tacky part consequently formed, and then heating the electronic circuit board, thereby fusing the solder and forming a solder precoat has been disclosed (refer, for example, to JP-A HEI 7-7244).

According to the method disclosed in JP-A HEI 7-7244, it has now become possible that a solder precoat is formed on a definite electronic circuit pattern by a simple operation and that an electronic circuit board of high reliability is consequently provided. This method, however, necessitates a measure to prevent accumulation of static electricity because it attaches the dry solder powder to the electronic circuit board and, as a result, inevitably suffers the powder to adhere to the uncalled-for part other than the necessary portions and also adhere excessively to the exposed metallic surface of the electronic circuit board. The attachment of solder by the dry technique suffers the powder to scatter and obstructs use of a fine pitch in the electronic circuit board. The fact that the excessively adhering solder powder is not easily recovered by a dry treatment hinders efficient utilization of the solder powder. This problem gains in conspicuity particularly when the solder powder in use is micropowder.

This invention, in a method for producing an electronic circuit board by treating an exposed metallic surface (electrically conductive circuit electrode surface) on an electronic circuit board with a tackifier compound, thereby imparting tackiness to the metallic surface, attaching solder powder to the resultant tacky part, and then heating the electronic circuit board, thereby fusing the solder and forming a solder precoat, is aimed at providing a method for strongly attaching the solder powder to the tacky part subsequent to carrying out an antistatic measure, a method for enabling addition to the amount of solder powder to be attached, a method for attaching the solder powder so that the circuit pattern is realized more definitely, a method for reusing the solder powder in a state not appreciably degraded after initial attachment, and a method for correcting the attachment of the solder powder to the electronic circuit board when the solder has not been attached sufficiently.

The present inventors, after making diligent efforts and studies with a view to solving the problems mentioned above, have perfected this invention.

### DISCLOSURE OF THE INVENTION

The first aspect of the invention provides a method for the attachment of solder powder, comprising the steps of treating an exposed metallic surface of an electronic circuit board with a tackifier compound, thereby imparting tackiness to the metallic surface to form a tacky part and supplying the tacky part with a solder powder slurry suspended in a liquid, thereby inducing attachment of the solder powder.

The second aspect of the invention provides the method set forth in the first aspect, wherein the liquid used for the solder powder slurry is deoxidized water or water having added an anticorrosive agent.

The third aspect of the invention provides a method for the removal of solder powder attached in advance by the method of attachment of solder powder set forth in the first or second aspect, comprising causing the electronic circuit board to be immersed in or sprayed with a liquid, thereby removing excessively attached solder powder.

The fourth aspect of the invention provides the method set forth in the third aspect, wherein the liquid to be used during the removal of the solder powder is deoxidized water or water having added an anticorrosive agent.

The fifth aspect of the invention provides the method set forth in the third or fourth aspect, wherein the excessively attached solder powder is removed by imparting vibration to the electronic circuit board or to the liquid used for immersion thereof

The sixth aspect of the invention provides the method set forth in the fifth aspect, wherein the vibration utilized during the removal of the excessively attached solder powder originates in a supersonic vibration imparted to the electronic circuit board or a liquid to which a supersonic vibration has been imparted.

The seventh aspect of the invention provides a method for the attachment of solder powder, comprising the steps of recovering in a form of slurry the solder powder removed by the method for the removal of solder powder set forth in any one of the third to sixth aspects and supplying the tacky part of the electronic circuit board with the recovered solder power in the form of slurry.

The eighth aspect of the invention provides a method for the production of a soldered electronic circuit board, comprising the steps of treating an exposed metallic surface of an electronic circuit board with a tackifier compound, thereby imparting tackiness to the metallic surface to form a tacky part, supplying the tacky part with a solder powder slurry suspended in a liquid, thereby inducing attachment of the solder powder, and thermally fusing the attached solder powder, thereby forming a circuit.

The ninth aspect of the invention provides a soldered electronic circuit board manufactured using the method for the production of a soldered electronic circuit board set forth in the eighth aspect.

The tenth aspect of the invention provides a method for the attachment of solder powder, comprising the steps of treating an exposed metallic surface of an electronic circuit board with a tackifier compound, thereby imparting tackiness to the metallic surface to form a tacky part, supplying the tacky part with a solder powder slurry suspended in a liquid, thereby inducing attachment of the solder powder and, on an occurrence of a part devoid of attachment of solder powder in the consequently formed electronic circuit board, supplying the part with a solder powder slurry, thereby inducing attachment of solder powder thereto.

By the method for the attachment of solder powder and the method for the production of an electronic circuit board by the use thereof according to this invention, it has become possible to form by a simple operation a definite solder circuit pattern deriving absolutely no trouble from static electricity and displaying a high strength in the attachment of solder powder and put the recovered solder powder to reuse. Particularly, they are capable of bringing about an effect of decreasing short circuits with the solder metal between the adjacent circuit paths even in a definite circuit pattern and markedly enhancing the reliability of an electronic circuit board. Further, by the method for the production of an electronic circuit board according to this invention, it has become possible to materialize miniaturization of a circuit board having electronic parts mounted thereon and impartation of high reliability thereto and allow provision of an electronic device possessing excellent characteristic properties.

The above and other objects, characteristic features and advantages of the present invention will become apparent to those skilled in the art from the description to be given herein below with reference to the accompanying drawing.

### BRIEF DESCRIPTION OF THE DRAWING

FIG. 1 is a schematic diagram illustrating a method for the attachment of solder powder contemplated by this invention.

### BEST MODE FOR CARRYING OUT THE INVENTION

The electronic circuit boards that constitute the subjects of this invention are single-sided electronic circuit boards, double-sided electronic circuit boards, multilayer electronic circuit boards and flexible electronic circuit boards which have a circuit pattern formed of a metal or other electrically conductive substance on a plastic substrate, a plastic film substrate, a glass fabric substrate, a paper-matrix epoxy resin substrate, a substrate having a metallic plate stacked on a wafer or a ceramic substrate, or an insulating substrate having a metallic matrix coated with plastic or ceramic substance, for example.

This invention relates to a method for attaching solder powder by treating an electrically conductive circuit electrode surface of the electronic circuit board with a tackifier compound, thereby imparting tackiness to the electrode surface, attaching solder powder to the resultant tacky part, and enabling the solder powder to be attached faithfully to a definite pattern while perfectly avoiding a trouble as due to static electricity and increasing the strength of attachment of the solder powder to the tacky part and to a method for producing a soldered electronic circuit board by placing the electronic circuit board having the solder powder attached thereto in a liquid, thereby depriving it of the solder powder attached to an uncalled-for part or to an excessive extent and subsequently heating the electronic circuit board, thereby fusing the attached solder powder and forming a solder circuit.

Though copper is used in most cases as the exposed electrically conductive substance that is destined to form a circuit, this invention does not need to restrict this substance to copper but only requires the substance to be an electrically conductive metal enabled to acquire tackiness on the surface by a tackifier compound which will be specifically described herein below. As concrete examples of the substance of this description, Ni, Sn, Ni—Au and metals including solder alloys may be cited.

As tackifier compounds preferably usable in this invention, naphthotriazole-based derivatives, benzotriazole-based derivatives, imidazole-based derivatives, benzoimidazole-based derivatives, mercaptobenzothiazole-based derivatives and benzothiazole thiofatty acids that are described in JP-A HEI 7-7244 may be cited. While these tackifier compounds exhibit a strong effect particularly to copper, they are capable of imparting tackiness to other electrically conductive substances as well.

This invention, prior to imparting tackiness to an electrically conductive circuit electrode surface on the electronic circuit board, selects at least one of the tackifier compounds enumerated above, dissolves it in water or acid water and adjusts the resultant solution to slight acidity of about pH 3 to 4 fit for use. As concrete examples of the substance to be used for the adjustment of pH, inorganic acids, such as hydrochloric acid, sulfuric acid, nitric acid and phosphoric acid, may be cited because the electrically conductive circuit electrode is made of a metal. The organic acids that can be used as well are formic acid, acetic acid, propionic acid, malic acid, oxalic acid, succinic acid and tartaric acid. Though the concentration of the tackifier compound is not rigidly restricted, it is properly adjusted to suit the solubility of the compound or the conditions of use. Preferably as a whole, the concentration in the range of 0.05 mass % to 20 mass % allows easy use. If it falls short of the lower limit of this range, the shortage will prevent a tacky film from being sufficiently formed, a fact that is detrimental to performance.

The treating temperature is preferably slightly higher than room temperature for the sake of the speed of formation and the amount of formation of the tacky film. Though it is not limitative but variable with the concentration of the tackifier compound and the kind of the metal, it is generally proper in the approximate range of 30° C. to 60° C. Though the treating time is not limitative, it is advantageous for the sake of the efficiency of operation to adjust the pH, the concentration of the tackifier compound, the treating temperature, and other conditions so that the treating time may fall in the range of 5 seconds to 5 minutes.

Incidentally, the presence of copper (univalent or divalent) in the concentration of 100 to 1000 ppm of ion in the solution in this case is at an advantage in enhancing efficiencies of formation of a tacky film, such as the speed of formation and the amount of formation.

The electronic circuit board to be treated is preferably treated with the solution of the tackifier compound after the electrically conductive circuit part requiring no solder other than the electrically conductive circuit electrode surface part to be soldered on the electronic circuit board has been coated as with a resist and only the electrically conductive circuit electrode part in the circuit pattern (the metallic surface exposed on the substrate) has been exposed.

At this point, tackiness is imparted to the electrically conductive circuit electrode surface when the electronic circuit board coated as with the resist is immersed in the solution of the tackifier compound or the electronic circuit board is coated or sprayed with the solution.

As concrete examples of the metallic composition of the solder powder to be used for the method of producing the electronic circuit board according to this invention, the Sn—Pb-based, Sn—Pb—Ag-based, Sn—Pb—Bi-based, Sn—Pb—Bi—Ag-based and Sn—Pb—Cd-based compositions may be cited. From the recent viewpoint of excluding Pb from the industrial waste, the Sb-free Sn—In-based, Sn—Bi-based, In—Ag-based, In—Bi-based, Sn—Zn-based, Sn—Ag-based, Sn—Cu-based, Sn—Sb-based, Sn—Au-based, Sn—Bi—Ag—Cu-based, Sn—Ge-based, Sn—Bi—Cu-based, Sn—Cu—Sb—Ag-based, Sn—Ag—Zn-based, Sn—Cu—Ag-based, Sn—Bi—Sb-based, Sn—Bi—Sb—Zn-based, Sn—Bi—Cu—Zn-based, Sn—Ag—Sb-based, Sn—Ag—Sb—Zn-based, Sn—Ag—Cu—Zn-based and Sn—Zn—Bi-based compositions prove to be particularly preferable.

When the electronic circuit board of this invention is manufactured by using an alloy composition selected from the Pb-free solders among other solder powders of the varying kinds of compositions enumerated above, particularly preferably from the solders containing Sn and Zn or Sn, Zn and Bi, or Sn and Ag or Sn, Ag and Cu, the parts to be mounted on the board are enabled to elongate service life and diversify.

As regards the particle diameter of the solder powder, the Japanese Industrial Standard (JIS) specifies such ranges as 53 to 22 μm, 45 to 22 μm and 38 to 22 μm determined by sifting. For determining the average particle diameter of the solder powder of this invention, the method utilizing standard sieves and a balance as laid down by JIS may be ordinarily used. Besides, the image analysis with a microscope or the Coulter counter according to the electrozone method is available as well for the determination. The Coulter counter, the principle of which is shown in “Powder Technology Handbook” (edited by the Society of Powder Technology, Japan, 2^{nd} edition, pp. 19-20), is intended to determine the particle diameter distribution of a given powder by passing the solution having the powder dispersed therein through a pore opened in a partition wall and measuring the change in electrical resistance on the opposite sides of the pore. It is capable of determining the ratio of numbers of particle diameters with high reproducibility. The average particle diameter of the solder powder of this invention can be decided by using the method described above.

In this invention, the attachment of the solder powder to the electronic circuit board provided in advance with tackiness is implemented by supplying the solder powder slurry suspended in a liquid to the tackiness-imparted surface of the electronic circuit board with the object of avoiding the trouble caused by static electricity. In this case, the slurry of the solder powder will not limit the direction of supply thereof toward the tackiness-imparted surface of the electronic circuit board.

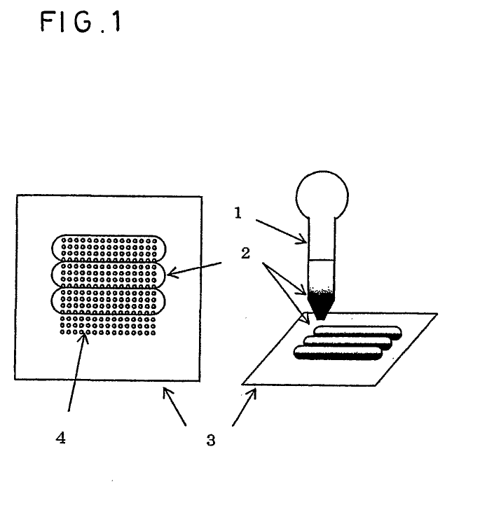

For the sake of increasing the thickness of attachment of the solder powder and adding to the strength of this attachment as well, however, the slurry is preferably supplied approximately perpendicularly to the tackiness-imparted surface of the electronic circuit board. FIG. 1 schematically illustrates the method for the attachment of the solder powder according to this invention. To be specific, this supply can be accomplished by having a tackiness-imparted surface 4 of an electronic circuit board 3 turn upward and supplying a slurry 2 of solder powder thereto from above selectively using a means like a dropping pipette. It is inferred that the solder powder is supplied perpendicularly to the tacky part and enabled to contact the tacky part strongly. Of course, the solder powder can be attached to the tacky part to a necessary degree even by supplying the slurry of solder powder parallel with the tackiness-imparted surface of the electronic circuit board. In this case, however, the strength of this attachment is lowered in comparison with the case where the slurry is supplied perpendicularly.

Incidentally, while the slurry is supplied using means like a dropping pipette in FIG. 1, it may be continuously supplied from a storage tank onto the tackiness-imparted surface of the electronic circuit board using a nozzle. During the attachment of solder powder or after the attachment thereof, preferably, vibration in the range of 0.1 Hz to several hundreds of Hz or in the range of several hundreds of kHz to several thousands of kHz is given to the electronic circuit board.

The concentration of the solder powder in the slurry is preferably as high as permissible within the range in which the solder powder remains fluid. For the purpose of enabling the solder powder to settle easily and avoid blocking, this concentration to be used advantageously is 80% or less and preferably about 30 to 50% of the concentration limited by the fluidity (critical concentration). Since the critical concentration is largely varied with the shape and size of solder particles, the flow rate of the slurry, the viscosity of the liquid and the exertion of vibration and can be easily tested, it is necessary that the critical concentration under the conditions of use be confirmed or that the conditions liable to induce blocking be confirmed in advance.

By causing the electronic circuit board having attached thereto the solder powder to be subsequently subjected to removal of excessive solder powder in a liquid, it is made possible to prevent the solder powder during the course of the removal from being attached by static electricity to the part devoid of tackiness or the solder powder from being coagulated by static electricity and enable use of a circuit board of a fine pitch or a solder micropowder.

When the step of attaching the solder powder is carried out by the dry technique, the electronic circuit board using a plastic substrate, for example, and tending to be statically charged tends to generate static electricity while the plastic surface thereof after having the solder powder attached thereto is rubbed as with a brush for the purpose of removing the excessive solder powder. When the solder powder is a solder micropowder, it tends to be attached even to the part that has shunned impartation of tackiness. As a result, the solder powder is attached to the uncalled-for part and suffered to induce short circuits between the adjacent circuit lines in a circuit pattern. This invention has solved this problem, i.e. the trouble caused by static electricity, by implementing the removal of the excessive solder powder in a liquid.

This invention, with the object of preventing static electricity from posing a trouble, allows use of water or a mixed solvent of water and a water-soluble low-boiling-point organic solvent as the liquid to be used for the solder powder slurry. It is water that proves preferable in consideration of problems, such as environmental pollution. In this case, for the purpose of preventing the solder power from being oxidized with the dissolved oxygen in the liquid, the water is preferably in the form of deoxidized water or plain water having added an anticorrosive agent.

Particularly when the recycle of the solder powder is contemplated, the deoxidized water and/or the plain water having added an anticorrosive agent proves to be advantageous for the sake of preventing the solder power from being oxidized with the dissolved oxygen in the liquid. As the deoxidized water, the water degassed by heating or the water having bubbled an inert gas, such as carbon dioxide gas, nitrogen or argon, therein can be used. When the deoxidized water and/or the water having added an anticorrosive agent is used, it proves to be convenient for the purpose of recycling the solder powder because the surface of the removed solder powder remains in a state prevented from being oxidized. Since the use of the anticorrosive agent necessitates subsequent washing with water, the use of the simply deoxidized water proves to be particularly favorable.

This invention allows the removal of the excessive solder powder to be implemented by having the electronic circuit board immersed in the liquid or sprayed with the liquid. Though the removal of the excessive solder powder may be achieved by gently stroking the surface of the electronic circuit board as with a brush in the liquid, it is preferably implemented by imparting vibration preferably in the range of 0.1 Hz to several hundreds of Hz or in the range of several hundreds of kHz to several thousands of kHz to the electronic circuit board or the solder-removing liquid. During the removal of the solder powder in the liquid, since the solder power removed into the solder-removing liquid readily settles, it can be easily recovered without inducing the phenomenon of scattering.

For the sake of preventing the solder powder used in this invention from being oxidized, the coating of the surface of the solder powder also proves to be a preferable method. As the coating agent for the solder powder, it is preferable to use at least one member selected from the group consisting of benzothiazole derivatives, amines possessing an alkyl group of a carbon number in the range of 4 to 10 in the side chain thereof, thiourea, silane coupling agents, lead, tin, gold, inorganic acid salts and organic acid salts. As the organic acid salt, it is preferable to use at least one member selected from the group consisting of lauric acid, myristic acid, palmitic acid and stearic acid.

The treating method of this invention can be effectively used for the formation of bumps serving to bond components of not only the solder-precoated circuit board mentioned above but also BGACSP (Ball Grid Array Chip Size Package) and FC. These devices are naturally embraced in the electronic circuit board of this invention.

The electronic circuit board which has been deprived of the excessive solder powder and has the solder powder attached to the tacky part thereof is then dried and subsequently subjected to the step of reflowing that heats and fuses the attached solder powder and gives rise to a soldered electronic circuit board. Since this heating is only required to fuse the solder powder attached to the tacky part, the treating temperature and the treating time can be easily decided by taking into consideration the melting point of the solder powder.

Since the excessive solder powder removed from the electronic circuit board in the liquid can be easily separated from the solder removing liquid, it can be gathered and recovered and directly, i.e. without being dried, put to use as the solder powder slurry, for the step of attaching the solder powder.

Incidentally, the solder powder slurry is forced out with a pump and used for the step of ordinary attachment of solder powder by the use of such means of supply as fluidizing the solder powder from the lower part till it overflows. As the means of supply, a means of the shape of a small-sized dropping pipette may be used as well.

When the part devoid of attachment of solder occurs after the electronic circuit board has undergone an ordinary soldering treatment, the part in question is provided with tackiness by a treatment with a tackifier compound and the resultant tacky part is supplied with the solder powder slurry by the use of means of supply, such as the dropping pipette. When the part devoid of attachment of solder occurs after the electronic circuit board has been provided with tackiness by a treatment with a tackifier compound and the solder powder has been attached to the resultant tacky part, it is supplied with the solder powder slurry by the use of a means of supply in the form of a small-sized dropping pipette. These measures may be used for repairing and correcting the solder circuit.

The soldered electronic circuit board fabricated by this invention can be used advantageously for a method for mounting an electronic part that comprises the steps of setting the electronic part in position and bonding the electronic part by causing a solder to reflow. For example, the solder precoat is formed by this invention on the electrodes of the electronic circuit board, the solder paste is applied thereto by the printing technique, the electronic parts (such as chip parts, CSP, etc.) are mounted on the solder paste, and the reflow heat source is actuated to effect solder bonding collectively. As the reflow heat source, a hot-air oven, an infrared heating furnace, a condensation soldering device, a light beam soldering device and the like are available.

Where the electrodes happen to use a pitch too fine to permit application of solder paste by printing, the bonding of electronic parts to the circuit board can be accomplished by printing a tacky flux on the electrodes provided in advance with a solder precoat and mounting the electronic parts (such as semiconductor chips) thereon or supplying the tacky flux to the bumps on the electronic parts, mounting the electronic parts on the electrodes provided in advance with a solder precoat, and subsequently causing the relevant media to reflow.

Further, methods of mounting semiconductor chips, such as a method which comprises forming Au bumps (stud bumps) on the electrodes of the semiconductor chip and bonding these Au bumps and the solder precoat formed on the electrodes of the circuit board by application of pressure and heat and a method which comprises supplying a nonconductive resin in the form of paste or sheet onto the circuit board and causing a semiconductor chip having Au bumps formed on the electrodes thereof to undergo thermo-compression bonding thereto by application of pressure and heat are also effectively used.

The process of reflowing contemplated by this invention is variable with the composition of soldering alloy. In the case of Sn—Zn-based alloys, such as 91 Sn/9Zn, 89Sn/8Zn/3Bi and 86Sn/8Zn/6Bi, the process is preferably implemented in two steps, preheating and reflowing. As regards the conditions of these two steps, the preheating temperature is in the range of 130 to 180° C., preferably 130 to 150° C., the preheating time in the range of 60 to 120 seconds, preferably 60 to 90 seconds, the reflowing temperature in the range of 210 to 230° C., preferably 210 to 220° C., and the reflowing time in the range of 30 to 60 seconds, preferably 30 to 40 seconds. The reflowing temperature in the other alloy system is in the range of +20 to +50° C., preferably +20 to +30° C., relative to the melting point of the alloy to be used. The other preheating temperature, preheating time and reflowing time may be in the same ranges as mentioned above.

The reflowing process can be implemented in nitrogen or in the air. In the case of nitrogen reflow, when the oxygen concentration is adjusted to 5 apparent volume % or less, preferably 0.5 apparent volume % or less, the treatment can be stabilized as compared with the case of open air reflow because the wetting property manifested by solder to the solder circuit is enhanced and the occurrence of solder balls is decreased.

### EXAMPLE 1

A printed-wiring board having a minimum electrode interval of 50 μm was fabricated. Copper was used for electrically conductive circuits. As a tackifier compound solution, an aqueous 2 mass % solution of an imidazole-based compound represented by following general formula (1)

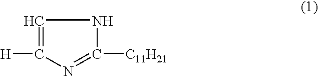

adjusted with acetic acid to a pH value of about 4 was used. The aqueous solution was heated to 40° C. In the heated aqueous solution, the printed-wiring board pretreated with an aqueous hydrochloric acid solution was immersed for 3 minutes to have a tacky substance formed on the surface of copper circuits.

Then, a slurry formed by dispersing a 96.5Sn/3.5Ag solder powder having an average particle diameter of about 20 μm at a concentration of 50 vol. % in deoxidized water was supplied onto the printed-wiring board using the device shown in FIG. 1 and simultaneously the printed-wiring board was exposed to a vibration of 50 Hz to induce attachment of the solder powder to the board. After the printed-wiring board was lightly vibrated in the deoxidized water and washed out, the printed-wiring board having the solder powder consequently attached thereto was dried.

The printed-wiring board, after being supplied with a flux by spraying, was placed in an oven at 240° C. and heated therein to fuse the solder powder and form a 96.5Sn/3.5Ag solder precoat having a thickness of about 20 μm on the exposed part of the copper circuit. Incidentally, the average particle diameter of the solder powder was determined by the use of a MICROTRAC®. The soldered circuit produced absolutely no bridge.

### EXAMPLE 2

A printed-wiring board provided with an area array using an electrode diameter of 70 μm and an electrode interval of 60 μm was fabricated. Copper was used for electrically conductive circuits.

As a tackifier compound solution, an aqueous 2 mass % solution of the same imidazole-based compound as used in Example 1 and adjusted with acetic acid to a pH value of about 4 was used. The aqueous solution was heated to 40° C. In the heated aqueous solution, the printed-wiring board pretreated with an aqueous hydrochloric acid solution was immersed for 3 minutes to have a tacky substance formed on the surface of copper circuits.

Then, a slurry formed by dispersing a 96.5Sn/3.5Ag solder powder having an average particle diameter of about 60 μm at a concentration of 50 vol. % in deoxidized water was supplied onto the printed-wiring board using the device shown in FIG. 1 and simultaneously the printed-wiring board was exposed to a vibration of 50 Hz. After the printed wiring board was lightly vibrated in the deoxidized water and washed out, the resultant printed-wiring board was dried.

The printed-wiring board, after being supplied with a flux by spraying, was placed in an over at 240° C. and heated therein to fuse the solder powder.

On the exposed part of copper circuits, 96.5Sn/3.5Ag solder bumps having a thickness of about 40 μm were formed.

Excellent bumps were formed on the solder circuits and defects, such as bridges and parts escaping bumping, were not formed at all.

### INDUSTRIAL APPLICABILITY

The method for producing a soldered electronic circuit board provided on the electrodes thereof with a solder precoat by imparting tackiness to the exposed metallic part on the substrate, attaching solder powder to the tacky part consequently formed, then removing the excessively attached solder powder in a liquid, and heating the electronic circuit board resulting from the removal of the excessively attached solder powder, thereby fusing the solder powder attains an effect of decreasing short circuits with a soldering metal between the adjacent circuit lines even in a fine circuit pattern and allows production of a soldered electronic circuit board having reliability markedly enhanced.

As a result, it has become possible to realize miniaturization of a circuit board having mounted thereon electronic parts possessing a fine circuit pattern and abounding in reliability, provide an electronic circuit board, a circuit board having mounted thereon electronic parts capable of realizing high reliability and high mounting density, and an electronic device excelling in characteristic properties, and enable application of the method of this invention to the production of electronic devices.

The factor of utilization of the solder powder can be enhanced because the recovered excessive solder powder can be recovered and recycled in the step for attachment of solder powder.

1. A method for the attachment of solder powder, comprising the steps of:
treating an exposed metallic surface of an electronic circuit board with a tackifier compound, thereby imparting tackiness to the metallic surface to form a tacky part; and
supplying the tacky part with a solder powder slurry suspended in a liquid, thereby inducing attachment of the solder powder.

2. A method according to claim 1, wherein the solder powder slurry is supplied perpendicularly to the tacky part of the exposed metallic surface of the electronic circuit board.

3. A method according to claim 1, wherein the liquid used for the solder powder slurry is deoxidized water or water having added an anticorrosive agent.

4. A method for the removal of solder powder attached in advance by the method of attachment of solder powder according to claim 1, comprising causing the electronic circuit board to be immersed in or sprayed with a liquid, thereby removing excessively attached solder powder.

5. A method according to claim 4, wherein the liquid to be used during the removal of the solder powder is deoxidized water or water having added an anticorrosive agent.

6. A method according to claim 4, wherein the excessively attached solder powder is removed by imparting vibration to the electronic circuit board or to the liquid used for immersion thereof.

7. A method according to claim 6, wherein the vibration utilized during the removal of the excessively attached solder powder originates in a supersonic vibration imparted to the electronic circuit board or a liquid to which a supersonic vibration has been imparted.

8. A method for the attachment of solder powder, comprising the steps of:
recovering in a form of slurry the solder powder removed by the method for the removal of solder powder according to claim 4; and
supplying the tacky part of the electronic circuit board with the recovered solder power in the form of slurry.

9. A method for the production of a soldered electronic circuit board, comprising the steps of:
treating an exposed metallic surface of an electronic circuit board with a tackifier compound, thereby imparting tackiness to the metallic surface to form a tacky part;
supplying the tacky part with a solder powder slurry suspended in a liquid, thereby inducing attachment of the solder powder; and
thermally fusing the attached solder powder, thereby forming a circuit.

10. A soldered electronic circuit board manufactured using the method for the production of a soldered electronic circuit board according to claim 9.

11. A method for the attachment of solder powder, comprising the steps of:
treating an exposed metallic surface of an electronic circuit board with a tackifier compound, thereby imparting tackiness to the metallic surface to form a tacky part;
supplying the tacky part with a solder powder slurry suspended in a liquid, thereby inducing attachment of the solder powder; and
on an occurrence of a part devoid of attachment of solder powder in the consequently formed electronic circuit board, supplying the part with a solder powder slurry, thereby inducing attachment of solder powder thereto.
